(19) United States
(12) Patent Application Publication
(10) Pub. No.: US 2010/0220522 A1
(43) Pub. Date: Sep. 2, 2010

(54) PHASE CHANGE RANDOM ACCESS MEMORY AND METHOD OF CONTROLLING READ OPERATION THEREOF

(75) Inventors: Hyung-rok Oh, Hwaseong-si (KR); Mu-hui Park, Seoul (KR); Du-eung Kim, Yongin-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/777,298

(22) Filed: May 11, 2010

Related U.S. Application Data
(63) Continuation of application No. 11/580,087, filed on Oct. 13, 2006.

(30) Foreign Application Priority Data
Oct. 15, 2005 (KR) 10-2005-0097269

(51) Int. Cl. G11C 11/00; G11C 8/08

(52) U.S. Cl. 365/163; 365/148; 365/230.06

(57) ABSTRACT

A phase change random access memory is provided which includes a memory array including a plurality of phase change memory cells, and wordlines respectively connected to the phase change memory cells, where, in a read operation, a voltage of a wordline connected to a selected phase change memory cell is transitioned between at least two voltage stages having different voltage levels.

### CROSS-REFERENCE TO RELATED APPLICATION

This is a Continuation of application Ser. No. 11/580,087, filed Oct. 13, 2006, which is incorporated herein by reference in its entirety.

### BACKGROUND OF THE INVENTION

1. Field of the Invention

The present invention generally relates to a phase change random access memory, and more particularly, the present invention relates to the control of wordline voltages of a phase change random access memory.

A claim of priority is made to Korean Patent Application No. 10-2005-0097269, filed on Oct. 15, 2005, in the Korean Intellectual Property Office, the disclosure of which is incorporated herein in its entirety by reference.

2. Description of the Related Art

A phase-change random access memory (PRAM), also known as an Ovonic Unified Memory (OUM), includes a phase-change material such as a chalcogenide alloy which is responsive to energy (e.g., thermal energy) so as to be stably transformed between crystalline and amorphous states. Such a PRAM is disclosed, for example, in U.S. Pat. Nos. 6,487,113 and 6,480,438.

The phase-change material of the PRAM exhibits a relatively low resistance in its crystalline state, and a relatively high resistance in its amorphous state. In conventional nomenclature, the low-resistance crystalline state is referred to as a ‘set’ state and is designated logic “0”, while the high-resistance amorphous state is referred to as a ‘reset’ state and is designated logic “1”.

The terms “crystalline” and “amorphous” are relative terms in the context of phase-change materials. That is, when a phase-change memory cell is said to be in its crystalline state, one skilled in the art will understand that the phase-change material of the cell has a more well-ordered crystalline structure when compared to its amorphous state. A phase-change memory cell in its crystalline state need not be fully crystalline, and a phase-change memory cell in its amorphous state need not be fully amorphous.

Generally, the phase-change material of a PRAM is reset to an amorphous state by joule heating of the material in excess of its melting point temperature for a relatively short period of time. On the other hand, the phase-change material is set to a crystalline state by heating the material below its melting point temperature for a longer period of time. In each case, the material is allowed to cool to its original temperature after the heat treatment. Generally, however, the cooling occurs much more rapidly when the phase-change material is reset to its amorphous state.

The speed and stability of the phase-change characteristics of the phase-change material are critical to the performance characteristics of the PRAM. As suggested above, chalcogenide alloys have been found to have suitable phase-change characteristics, and in particular, a compound including germanium (Ge), antimony (Sb) and tellurium (Te) (e.g., Ge₂Sb₂Te₅ or GST) exhibits a stable and high speed transformation between amorphous and crystalline states.

The read operation of the PRAM enables bit lines and wordlines to select a specific memory cell, and applies an external current to the PRAM to generate a cell current flowing through the memory cell, the magnitude of which is dependent on the resistance of the phase change material of the PRAM. To read data “1” or “0”, a current sense amplifier senses a reference current and a current variation in the selected memory cell, or a voltage sense amplifier senses a reference voltage and a voltage variation in the selected memory cell.

FIG. 1 is a diagram illustrating circuitry associated with a read operation of a conventional PRAM 100, and FIG. 2 is a timing diagram for explaining the read operation of the conventional PRAM 100 of FIG. 1.

Referring to FIG. 1, a plurality of phase change memory cells each include a phase change material GST and a cell transistor CTR connected between a bit line BL and respective word lines WL_0 through WL_N. The word lines WL_0 through WL_N are connected to a word line driver which, in the example, includes a plurality of invertors.

The bit line BL is connected to a data node V(DATA) through a selection transistor which receives a Y address signal, and a voltage clamping transistor which receives a clamp signal VCMP. Also, an enable transistor is connected as shown and receives a read operation control signal WEb. A current source IREAD is connected between a boosted voltage VDD and the data node V(DATA), and generates the current required for the read operation. Further, a precharge transistor is connected between a source voltage VCC and the data node V(DATA), and receives a precharge signal PREB. Still further, a sense amplifier S/A compares a reference voltage VREF with a voltage of the data node V(DATA), and generates a corresponding output data OUT.

Referring to FIG. 2, in the read operation, the read operation control signal WEb is enabled to LOW, and a column select signal Y is enabled to HIGH, thereby selecting the bit line BL. Further, the precharge signal PREB is enabled to LOW to precharge an input port of a sense amplifier S/A.

A selected wordline is then enabled while the voltage of the bit line BL is clamped by a clamp signal VCMP. If the wordline WL_0 is enabled, for example, a signal applied to the wordline WL_0 has a rectangular waveform, and as a result, and a cell current iCELL flows through the bit line BL, and the phase change material GST and the cell transistor CTR connected to the wordline WL_0. However, as shown in FIG. 2, the waveform of the cell current iCELL flowing through the phase change memory cell generally exhibits a brief spike. Repeated spikes in the cell current iCELL can deteriorate the phase change material of the phase change memory cell and reduce the reliability of the PRAM device.

### SUMMARY OF THE INVENTION

According to an aspect of the present invention, a phase change random access memory is provided which includes a memory array including a plurality of phase change memory cells, and wordlines respectively connected to the phase change memory cells, where, in a read operation, a voltage of a wordline connected to a selected phase change memory cell is transitioned between at least two voltage stages having different voltage levels.

According to another aspect of the present invention, a phase change random access memory is provided which includes a memory array including a plurality of phase change memory cells respectively connected to a plurality of wordlines, a plurality of decoders which output selection voltages in response to an address signal, a plurality of wordline drivers which respectively control voltages of the wordlines in response to the selection voltages of outputs of decoders, and a voltage controller which controls the supply of drive voltages to the decoders, wherein the drive voltages include at least two power supply voltages having different voltage levels.

According to another aspect of the present invention, a phase change random access memory is provided which includes a memory array including a plurality of phase change memory cells, and a plurality of wordline drivers which control voltages of wordlines respectively connected to the phase change memory cells, where, in a read operation, a voltage of a wordline connected to a selected phase change memory cell is transitioned between at least two voltage stages having different voltage levels.

According to an aspect of the present invention, a method is provided of controlling a read operation of a phase change random access memory including a plurality of phase change memory cells. The method includes controlling the voltage of a wordline connected to a selected phase change memory cell using a signal including at least two stages having different voltage levels.

### BRIEF DESCRIPTION OF THE DRAWINGS

The above and other features and advantages of the present invention will become readily apparent from the detailed description that follows, with reference to the accompanying drawings, in which:

FIG. 1 is a circuit diagram for explaining a read operation of a PRAM;

FIG. 2 is a timing diagram for explaining the read operation of FIG. 1;

FIG. 3 is a circuit diagram of a PRAM according to an embodiment of the present invention;

FIG. 4A is a circuit diagram of a voltage controller and a decoder of FIG. 3 according to an embodiment of the present invention;

FIG. 4B is a timing diagram for explaining the operation of the voltage controller and the decoder of FIG. 4A;

FIG. 5A is a circuit diagram of the voltage controller and the decoder of FIG. 3 according to another embodiment of the present invention;

FIG. 5B is a timing diagram for explaining the operation of the voltage controller and the decoder of FIG. 5a;

FIG. 6 is a block diagram of a PRAM according to another embodiment of the present invention;

FIG. 7A is a circuit diagram of a voltage controller and a decoder of FIG. 6;

FIG. 7B is a timing diagram for explaining the operation of the voltage controller and the decoder of FIG. 7A;

FIG. 8 is a block diagram of a PRAM according to another embodiment of the present invention;

FIG. 9A is a circuit diagram of a wordline driver of FIG. 8;

FIG. 9B is a timing diagram for explaining the operation of the wordline driver of FIG. 9B;

FIG. 10 is a block diagram of a PRAM according to another embodiment of the present invention;

FIG. 11A is a circuit diagram of a wordline driver of FIG. 10; and

FIG. 11B is a timing diagram for explaining the operation of the wordline driver of FIG. 11A.

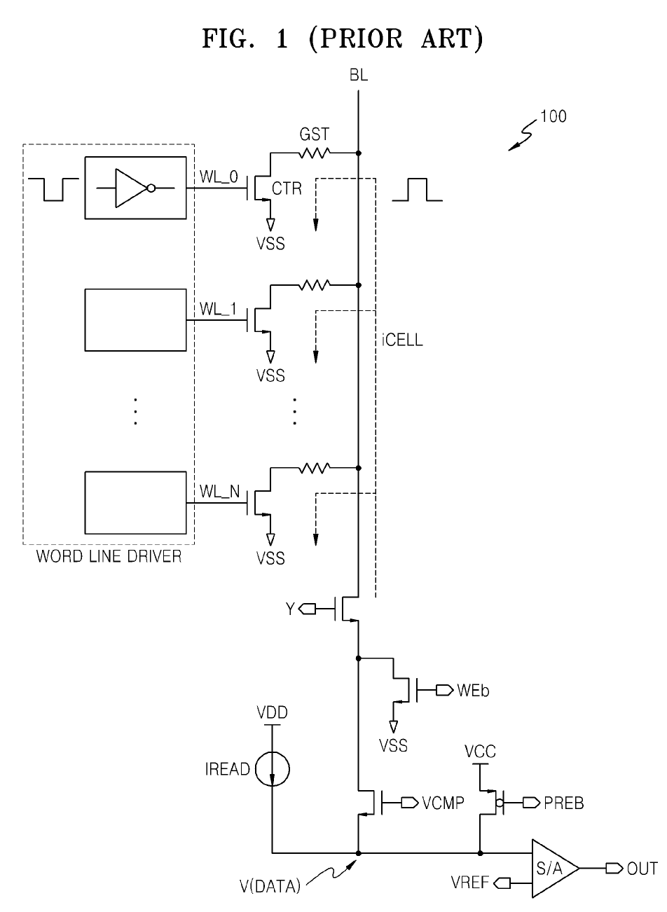

### DETAILED DESCRIPTION OF EMBODIMENTS

The present invention will now be described more fully with reference to the accompanying drawings, in which exemplary embodiments of the invention are shown. The invention may, however, be embodied in many different forms, and should not be construed as being limited to the embodiments set forth herein; rather, these embodiments are provided so that this disclosure will be thorough and complete, and will fully convey the concept of the invention to those skilled in the art. Throughout the drawings, like reference numerals refer to like elements.

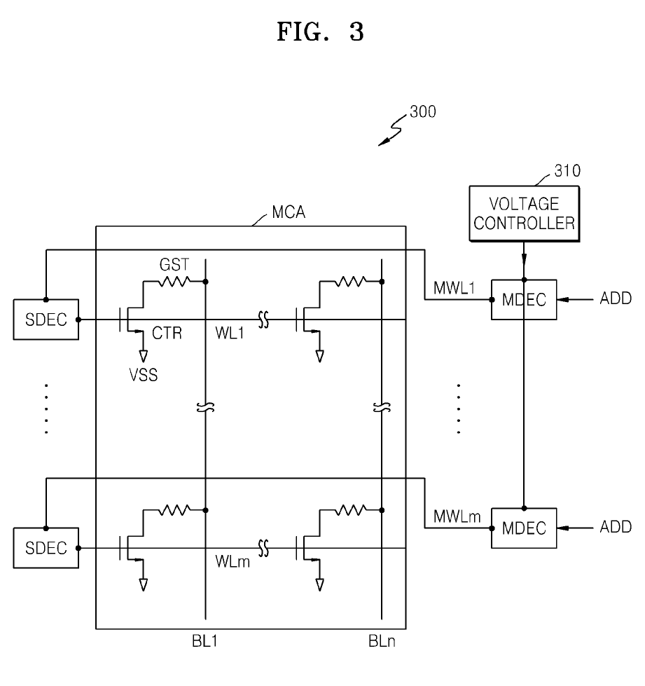

FIG. 3 is a block diagram of a PRAM 300 according to an embodiment of the present invention. Referring to FIG. 3, the PRAM 300 includes a memory array MCA having a plurality of phase change memory cells, a plurality of decoders MDEC, a plurality of wordline drivers SDEC, and a voltage controller 310.

Each of the phase change memory cells of this example includes a phase change material GST and a cell transistor CTR connected in series between a corresponding one of a plurality of bit lines BL1 through BLn and a corresponding one of a plurality of wordlines WL1 through WLm.

The plurality of decoders MDEC select phase change memory cells of the memory array MCA in response to an address signal ADD by controlling the respective wordline drivers SDEC via decoder outputs MWL1 through MWLm. The wordline drivers SDEC control the voltages of wordlines WL1 through WLm respectively connected to the phase change memory cells in response to the voltages of the corresponding decoder outputs MWL1 through MWLm.

The voltage controller 310 controls a voltage for driving the decoders MDEC. As will be explained in more detail below, the voltage controller 310 supplies at least two different power supply voltages. That is, the voltage controller 310 sequentially applies a power supply voltage having a low level and a power supply voltage having a high level to the decoders MDEC.

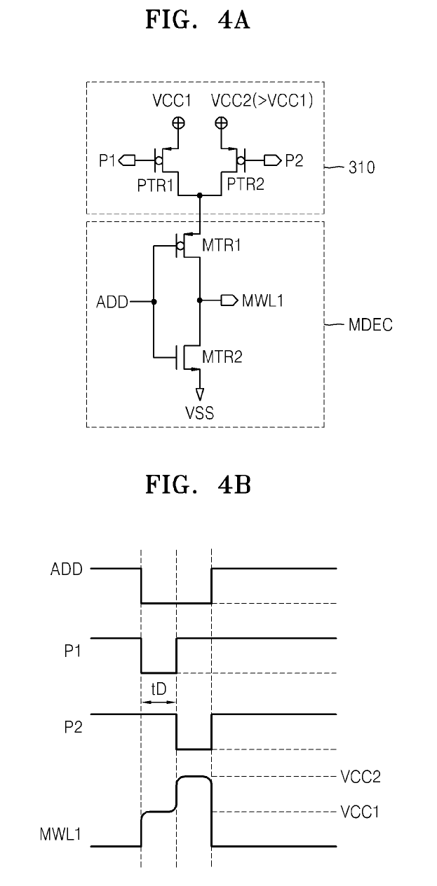

FIG. 4A is a circuit diagram of the voltage controller 310 and the decoder DEC of FIG. 3 according to an embodiment of the present invention, and FIG. 4B is a timing diagram for explaining the operation of the voltage controller and the decoder of FIG. 4A.

Referring to FIG. 4A, the voltage controller 310 includes a first power supply voltage VCC1, a second power supply voltage VCC2 that is higher than the first power supply voltage VCC1, a first switch PTR1 which is connected to the first power supply voltage VCC1 and applies the first power supply voltage VCC1 to the corresponding decoder MDEC in response to a first control signal P1, and a second switch PTR2 which is connected to the second power supply voltage VCC2 and applies the second power supply voltage VCC2 to the corresponding decoder MDEC in response to a second control signal P2. The first and second switches PTR1 and PTR2 can be transistors. In the example of FIG. 4A, the first and second switches are PMOS transistors.

The decoder MDEC of FIG. 4A includes an inverter which receives the address signal ADD and outputs the decoder output signal MWL1. In the example, the inverter of the decoder MDEC includes a PMOS transistor MTR1 and an NMOS transistor MTR2 serially connected between the voltage controller 310 and a ground voltage VSS. However, the structure of the decoder MDEC is not limited to the inverter structure of FIG. 4A.

The operation of the voltage controller 310 and the decoder MDEC will now be explained with reference to FIG. 4B.

Assuming that a wordline WL1 is selected in the read operation, the PMOS transistor MTR1 of the decoder MDEC is turned on when the address signal ADD is enabled to a low level. When the first control signal P1 is enabled to a low level, the first switch PTR1 is turned on and the first power supply voltage VDD1 is output as a decoder output WL1. When the first control signal P1 is enabled to a high level and the second control signal P2 is enabled to a low level after a predetermined time tD, the second switch PTR2 is turned on and the second power supply voltage VCC2 is output as the decoder output MLW1. The first and second control signals P1 and P2 respectively control the first and second switches PTR1 and PTR2.

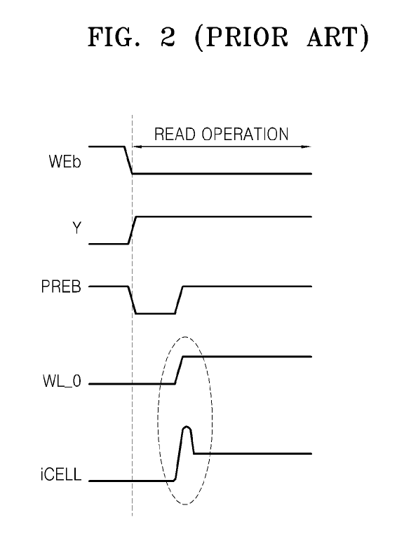

The decoder output MWL1 is applied to a corresponding wordline driver SDEC. The wordline driver SDEC is driven by the decoder output MWL1 and controls the wordline WL1 in response to variations in the voltage of the decoder output MWL1. Accordingly, the voltage of the word line WL1 has a waveform as shown in FIG. 4B. That is, the voltage of the selected wordline WL1 is not abruptly increased all at once, as shown in FIG. 2, but instead is increased in stages from a lower voltage to a high voltage. Thus, it is possible to prevent or reduce the presence of a spike in the current flowing through memory cells. This helps to prevent deterioration of the phase change material and improves the reliability of the PRAM.

While FIGS. 4A and 4B illustrate the voltage of the wordline as having two stages, the voltage of the wordline can have more than two stages.

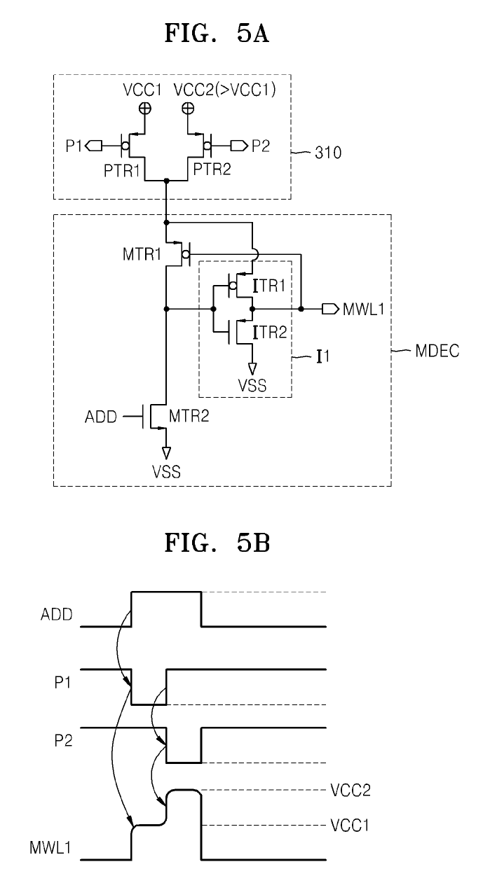

FIG. 5A is a circuit diagram of the voltage controller 310 and the decoder MDEC of FIG. 3 according to another embodiment of the present invention, and FIG. 5B is a timing diagram for explaining the operation of the voltage controller 310 and the decoder MDEC of FIG. 5Aa.

Referring to FIG. 5A, the voltage controller 310 of this embodiment is the same as that of previously described FIG. 4A. Accordingly, a detailed description thereof is omitted here to avoid redundancy.

The decoder MDEC of FIG. 5A includes transistors MTR1 and MTR2 connected in series between the voltage controller 310 and a ground voltage VSS, and an inverter I1. The inventor I1 of this example includes a PMOS transistor ITR1 and an NMOS transistor ITR2 as shown in FIG. 5A. The source of the PMOS transistor ITR1 of the inverter I1 is connected to a power supply voltage applied by the voltage controller 310.

Assuming that the input node of the inverter I1 is precharged to a high level while the transistor MTR2 is turned off when the address signal ADD is at a low level, when the address signal ADD is enabled to a high level, the transistor MTR2 is turned on, the transistor MTR1 is turned off and the input node of the inverter I1 is at a low level. Thus, the PMOS transistor ITR1 is turned on to sequentially receive the first power supply voltage VCC1 and the second power supply voltage VDD2 applied by the voltage controller 310. The operation principles of the voltage controller 310 and the decoder MDEC of FIG. 5A are otherwise similar to those of the voltage controller 310 and the decoder MDEC of FIG. 4A. Accordingly, further explanation is omitted here to avoid redundancy.

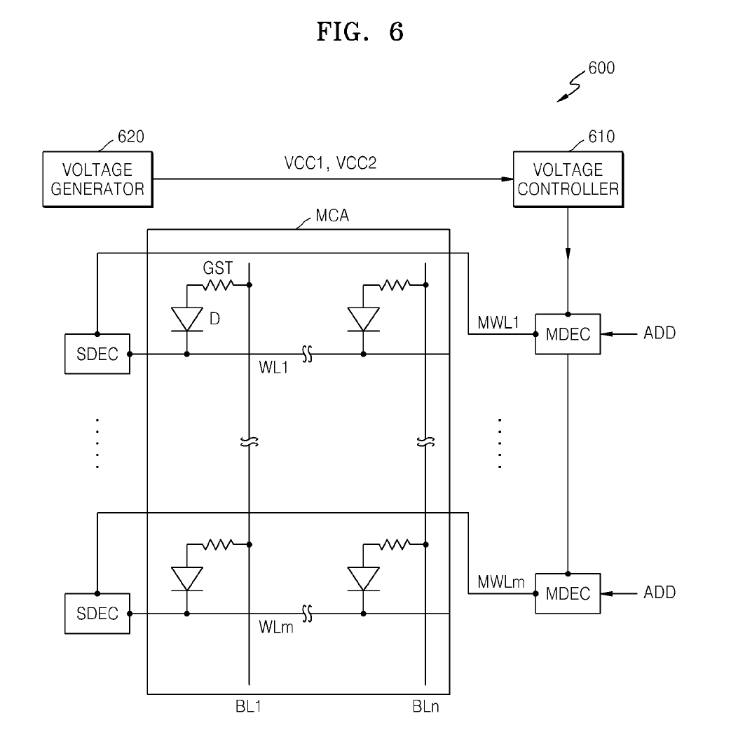

FIG. 6 is a block diagram of a PRAM 600 according to another embodiment of the present invention. The PRAM 600 includes a memory array MCA having a plurality of phase change memory cells, a plurality of decoders MDEC, a plurality of wordline drivers SDEC, and a voltage controller 310. Also illustrated in FIG. 6 is a voltage generator 620 which outputs supply voltages VCC1 and VCC2.

Referring to FIG. 6, each of the phase change memory cells of the PRAM 600 includes a phase change material GST and a diode D connected in series between a corresponding one of plural bit lines BL1 through BLn and a corresponding one of plural wordlines WL1 through WLm.

The plurality of decoders MDEC select phase change memory cells of the memory array MCA in response to an address signal ADD by controlling the respective wordline drivers SDEC via decoder outputs MWL1 through MWLm. The wordline drivers SDEC control the voltages of wordlines WL1 through WLm respectively connected to the phase change memory cells in response to the voltages of the corresponding decoder outputs MWL1 through MWLm.

The voltage controller 610 controls a voltage for driving the decoders MDEC. As will be explained in more detail below, the voltage controller 610 supplies at least two different power supply voltages provided by the voltage generator 620. That is, in the example given below, the voltage controller 610 sequentially applies supply voltage VCC1 having a high level and the supply voltage VCC2 having a low level to the decoders MDEC.

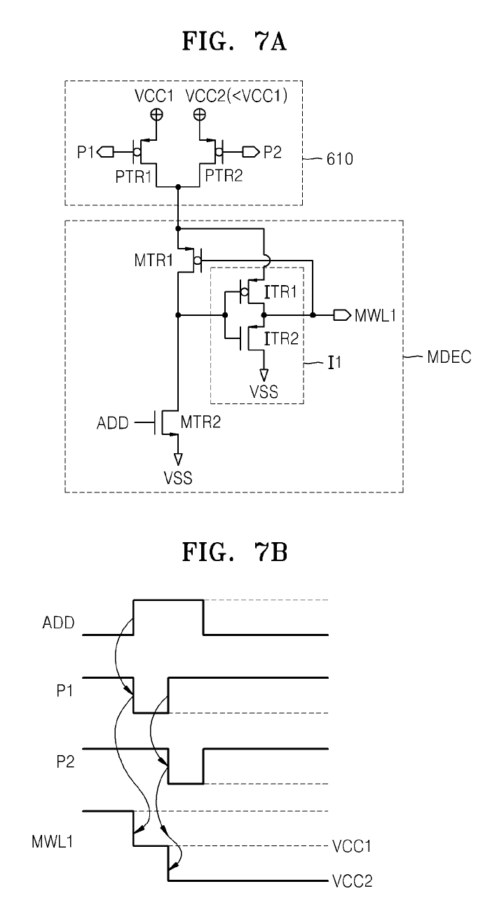

FIG. 7A is a circuit diagram of a voltage controller 610 and a decoder MDEC of FIG. 6, and FIG. 7B is a timing diagram for explaining the operation of the voltage controller and the decoder of FIG. 7B.

Referring to FIG. 7A, the voltage controller 610 has the same configuration as the voltage controller 310 of FIG. 5A, and the decoder MDEC has the same configuration as the decoder MDEC of FIG. 5A. Accordingly, a detailed description thereof is omitted here to avoid redundancy. It is noted, however, that unlike the previous embodiments, the second power supply voltage VCC2 is lower than the first power supply voltage VCC1 in the embodiment of FIG. 7A. Accordingly, when the first switch PTR1 and the second switch PTR2 are turned on and off sequentially in response to the first control signal P1 and the second control signal P2, the voltage of the wordline WL1 has a stepped down waveform as shown in FIG. 7B. This is because phase change memory cells utilize a diode D as a selection element, and thus the selected wordline WL1 should have a low voltage. Accordingly, by sequentially reducing the voltage of the wordline WL1, the presence of spikes in the current flowing through the phase change memory cells in the read operation can be reduce or prevented. As such, deterioration of the phase change material is reduced, and reliability of the PRAM is improved.

The voltage controllers 310 and 610 of FIGS. 3 and 6 may be respectively arranged in conjunction regions of the PRAMs 300 and 600. This can minimize the circuit area required for the voltage controllers 310 and 610.

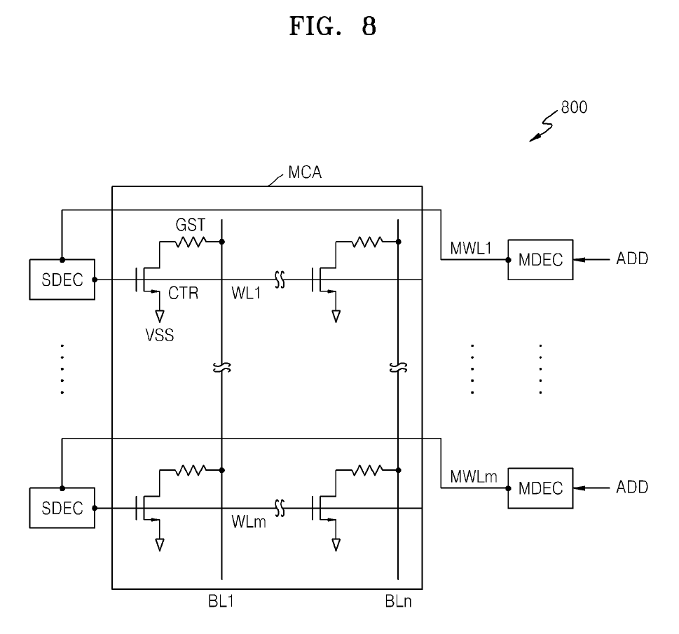

FIG. 8 is a block diagram of a PRAM 800 according to another embodiment of the present invention. As shown, the PRAM 800 includes a memory cell array MCA, a plurality of decoders MDEC, and a plurality of wordline drivers SDEC.

Referring to FIG. 8, the PRAM 800 includes a memory array MCA having a plurality of phase change memory cells and a plurality of wordline drivers SDEC controlling the voltages of wordlines WL1 through WLm respectively connected to the phase change memory cells. Each of the phase change memory cells includes a phase change material GST and a transistor CTR connected in series between a corresponding one of bit lines BL1 through BLn and a corresponding one of the wordlines WL1 through WLm.

As with the previous embodiments, the read voltage of a selected wordline has at least two stages having different voltages. However, unlike the previous embodiments, the PRAM 800 of FIG. 8 does not include a voltage controller. That is, in the PRAM 800, the wordline driver SDEC controls a selected wordline such that the voltage of the wordline has at least two stages having sequentially increased voltages.

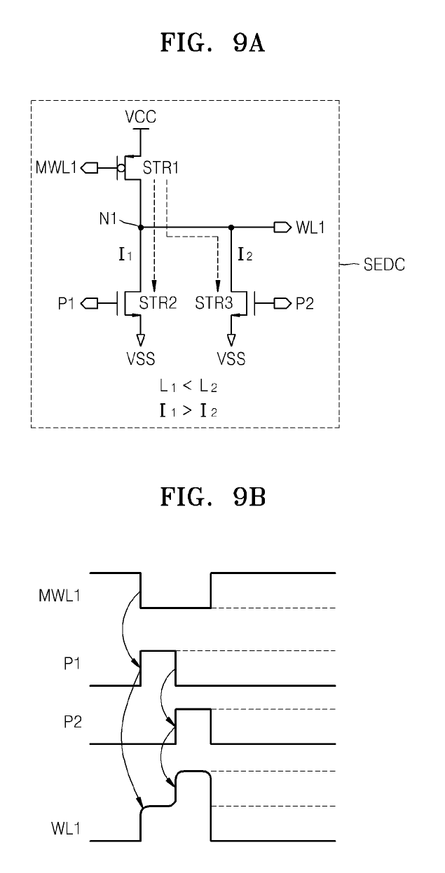

FIG. 9A is a circuit diagram of a wordline driver SDEC of FIG. 8, and FIG. 9B is a timing diagram for explaining the operation of the wordline driver SDEC of FIG. 9A.

Referring to FIG. 9A, the wordline driver SDEC includes a first switch STR1 connected between a power supply voltage VCC and a node N1. The first switch is turned on and off in response to a corresponding decoder output MWL1 output from a corresponding decoder MDEC. In the example of this embodiment, the decoder output MWL1 output from the corresponding decoder MDEC corresponds to an inverted address signal ADD (see FIG. 8). The wordline driver SDEC further includes a second switch STR2 connected between the first node N1 and a ground voltage VSS, which is turned on or off in response to a first control signal P1, and a third switch STR3 connected between the first node N1 and the ground voltage VSS, which is turned on or off in response to the second control signal P2.

A channel length L1 of the second switch STR2 is less than a channel length L2 of the third switch STR3.

Referring to FIG. 9B, when the first switch STR1 is turned on in response to the decoder output MWL1 becoming a low level, the first control signal is enabled to a high level. As such, the second switch STR2 is turned on and a current I1 flows. Then, the second control signal P2 is enabled to a high level after the first control signal P1 is disabled, and thus the third switch STR3 is turned on and a current I2 flows.

Since the channel length L2 of the third switch STR3 is greater than the channel length L1 of the second switch STR2, the current I1 flowing through the second switch STR2 is greater than the current I2 flowing through the third switch STR3. This is because the current flowing through a transistor is inversely proportional to the channel length of the transistor.

The voltage of the first node N1 becomes much lower than the power supply voltage VCC when the current I1 is large, but becomes only slightly lower than the power supply voltage VCC when the current I2 is small. Because the voltage of the first node N1 controls the voltage of the wordline WL1, the voltage of the wordline WL1 has the waveform as shown in FIG. 9B. Here, the power supply voltage VCC is equal to the voltage of the decoder output MWL1 output from the decoder MDEC. That is, the PRAM 800 controls the voltage of the decoder output MWL1 such that the wordline WL1 has more than two stages of sequentially increasing voltages. Accordingly, sequentially reducing the voltage of the wordline WL1 helps avoids a spike current from flowing through the phase change memory cell in the read operation, which prevents or reduces deterioration of the phase change material and improves the reliability of the PRAM.

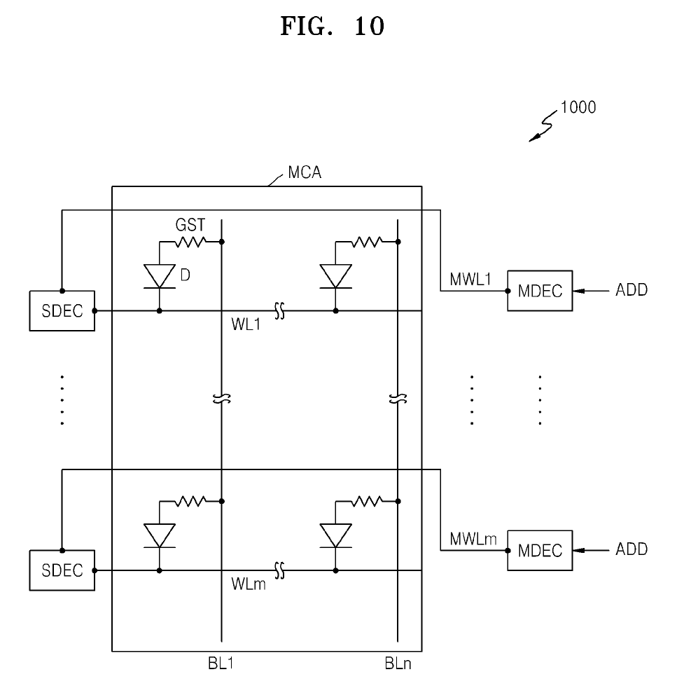

FIG. 10 is a block diagram of a PRAM 1000 according to another embodiment of the present invention.

Referring to FIG. 10, each of phase change memory cells of the PRAM 1000 includes a phase change material GST and a diode D connected in series between a corresponding bit line and a corresponding wordline. Except as noted below, the remainder of the PRAM 1000 of FIG. 10 is similar to the PRAM 800 of FIG. 8, and accordingly, a detailed description thereof is omitted here to avoid redundancy.

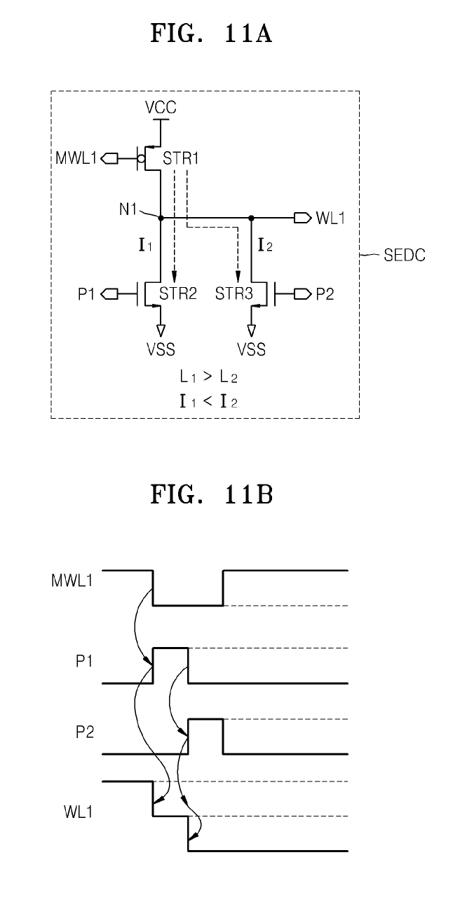

FIG. 11A is a circuit diagram of a wordline driver SDEC of FIG. 10, and FIG. 11B is a timing diagram for explaining the operation of the wordline driver SDEC of FIG. 11A.

Referring to FIG. 11A, the wordline driver SDEC controls a selected wordline such that the wordline has at least two stages having sequentially decreasing voltages. The configuration of the wordline driver SDEC of FIG. 11A is identical to the configuration of the wordline driver SDEC of FIG. 9A, except for the relationship between the channel lengths of the second and third switches STR2 and STR3. That is, in FIG. 11A, the channel length L1 of the second switch STR2 is greater than the channel length L2 of the third switch STR3 in the wordline driver SDEC. Thus, the current I1 flowing through the second switch STR2 is smaller than the current I2 flowing through the third switch STR3, and the voltage of the first node N1 when the current I2 is flowing is lower than when the current I1 is flowing. The voltage of the first node N1 controls the voltage of the wordline WL1, and thus the voltage of the wordline WL1 exhibits a waveform as shown in FIG. 11B.

Since the phase change memory cell of FIG. 10 includes the phase change material GST and the diode D, the selected wordline WL1 should have a low selection voltage. Accordingly, sequentially reducing the voltage of the wordline WL1 avoids a spike current from flowing through the phase change memory cell in the read operation, which in turn prevents or reduces deterioration of the phase change material and improves reliability of the PRAM.

A method of controlling the read operation of a PRAM including a plurality of phase change memory cells according to an embodiment of the present invention includes controlling the voltage of a wordline connected to a selected phase change memory cell using a signal having at least two stages having different voltages. The method of controlling the read operation depends on the configuration of the phase change memory cell of the PRAM. When the phase change memory cell includes a phase change material and a transistor connected in series between a corresponding bit line and a corresponding wordline, the voltage of the signal includes at least two stages having sequentially increasing voltages. When the phase change memory cell includes a phase change material and a diode connected in series between a corresponding bit line and a corresponding wordline, the voltage of the signal includes at least two stages having sequentially decreasing voltages.

The signal is used for the wordline driver of the PRAM to control the voltage of the wordline connected to a selected phase change memory cell. The method of controlling the read operation of a PRAM corresponds to the operation of the PRAMs 300, 600, 800 and 1000, so a detailed explanation thereof is omitted.

As described above, the PRAM and the method of controlling the read operation of the PRAM according to the present invention can control the voltage of a selected wordline to have multiple stages in the read operation. This prevents or reduces deterioration of the phase change material otherwise caused by current spikes flowing through phase change memory cells. As such, reliability of the PRAM may improve.

While the present invention has been particularly shown and described with reference to exemplary embodiments thereof, it will be understood by those of ordinary skill in the art that various changes in form and detail may be made therein without departing from the spirit and scope of the present invention as defined by the following claims.

What is claimed is:

1. A phase change random access memory, comprising:
a memory array including a plurality of phase change memory cells; and
wordlines respectively connected to the phase change memory cells,
wherein voltages of wordlines is respectively controlled by a plurality of wordline drivers,
wherein, in a read operation, a voltage of a wordline connected to a selected phase change memory cell is transitioned between at least two voltage stages having different voltages, and
wherein the at least two stages have sequentially decreasing voltages.

2. The phase change random access memory of claim 1, wherein, a transition of the voltage of a wordline connected to the selected phase change memory cell is completed before the read operation is completed,

3. The phase change random access memory of claim 1, further comprising a bit line connected to the phase change memory cells, wherein each of the plurality of phase change memory cells includes a phase change material and a diode connected in series between the bit line and a respective wordline.

4. A phase change random access memory comprising:
a memory array including a plurality of phase change memory cells respectively connected to a plurality of wordlines;
a plurality of decoders which output selection voltages in response to an address signal;
a plurality of wordline drivers which respectively control voltages of the wordlines in response to the selection voltages output from decoders; and
a voltage controller which controls the supply of drive voltages to the decoders, wherein the drive voltages include at least two different power supply voltages,
wherein the voltage controller sequentially applies a power supply voltage having a high level and a power supply voltage having a low level to a corresponding decoder in a read operation.

5. The phase change random access memory of claim 4, wherein the plurality of decoders output the drive voltages controlled by the voltage controller as the selection voltages to the plurality of wordline drivers during the address signal is activated.

6. The phase change random access memory of claim 4, wherein the voltage controller comprises:
a first power supply voltage;
a second power supply voltage which is lower than the first power supply voltage;
first and second switches which sequentially apply the first and second power supply voltages, respectively, to a corresponding decoder in response to at least one control signal.

7. The phase change random access memory of claim 6, further comprising a bit line connected to the phase change memory cells, wherein each of the phase change memory cells includes a phase change material and a diode connected in series between the bit line and a corresponding wordline.

8. The phase change random access memory of claim 4, wherein the voltage controller comprises:
a first switch configured to be connected between a first power supply voltage and a first node, and turned on in response to a first control signal;
a second switch configured to be connected between a second power supply voltage and the first node, and turned on in response to a second control signal,
wherein the second power supply voltage is lower than the first power supply voltage, the first node is connected with the corresponding decoder, and the second switch is turned on after the first switch is turned on.

9. The phase change random access memory of claim 8, wherein the first control signal and the second control signal is sequentially activated during the address signal is activated.

10. The phase change random access memory of claim 8, wherein one of the first switch and the second switch is turned on during the address signal is activated.

11. The phase change random access memory of claim 8, further comprising a bit line connected to the phase change memory cells, wherein each of the phase change memory cells includes a phase change material and a diode connected in series between the bit line and a corresponding wordline.

12. The phase change random access memory of claim 4, wherein the voltage controller is arranged in a conjunction region of the memory.

13. A phase change random access memory comprising:
a memory array including a plurality of phase change memory cells; and
a plurality of wordline drivers which control voltages of wordlines respectively connected to the phase change memory cells,
wherein, in a read operation, a voltage of a wordline connected to a selected phase change memory cell is transitioned between at least two voltage stages having different voltages,
wherein the voltage of the wordline includes at least two stage having sequentially decreasing voltages.

14. The phase change random access memory of claim 13, wherein, a transition of the voltage of a wordline connected to the selected phase change memory cell is completed before the read operation is completed.

15. The phase change random access memory of claim 13, wherein each wordline driver comprises:
a first switch connected between a power supply voltage and a first node and turned on or off in response to an address signal;
a second switch connected between the first node and a ground voltage and turned on or off in response to a first control signal; and
a third switch connected between the first node and the ground voltage and turned on or off in response to a second control signal,
wherein the third switch is turned on and turned off after the second switch is turned on and turned off, and a channel length of the second switch is greater than a channel length of the third switch.

16. The phase change random access memory of claim 15, wherein the first control signal and the second control signal is sequentially activated during the address signal is activated.

17. The phase change random access memory of claim 15, wherein one of the second switch and the third switch is turned on during the address signal is activated.

18. The phase change random access memory of claim 15, wherein the address signal is a decoded address signal.

19. The phase change random access memory of claim 15, further comprising a bit line connected to the phase change memory cells, wherein each of the phase change memory cells includes a phase change material and a diode connected in series between the bit line and a corresponding wordline.

20. The phase change random access memory of claim 15, wherein the power supply voltage corresponds to a drive voltage of the wordline driver.
